(19) United States
(12) Patent Application Publication
(10) Pub. No.: US 2017/0184497 A1
(43) Pub. Date: Jun. 29, 2017

(54) PLASMONIC NANOPARTICLES WITH HIDDEN CHIROPTICAL ACTIVITY

(71) Applicant: Hong Kong Baptist University, Hong Kong (HK)

(72) Inventors: Zhifeng Huang, Hong Kong (HK); Junjun Liu, Hong Kong (HK); Lin Yang, Hong Kong (HK)

(21) Appl. No.: 15/393,397

(22) Filed: Dec. 29, 2016

Related U.S. Application Data
(60) Provisional application No. 62/272,213, filed on Dec. 29, 2015.
(60) Provisional application No. 62/408,836, filed on Oct. 17, 2016.

(51) Int. Cl. G01N 21/552; C23C 14/50; C23C 14/16; C23C 14/30

(52) U.S. Cl. CPC G01N 21/554; C23C 14/30; C23C 14/505; C23C 14/16

(57) ABSTRACT

A method is presented to minimize the helical pitch (P) of chiroplasmonic nanostructures to the molecular size-comparable scale. In particular, chiroplasmonic nanostructures can be used to induce plasmonic chirality via chirality transfer and used for chirality-related primary applications such as chiral sensing. In one aspect, there is provided a chiroptically active plasmonic nanoparticle with a helical pitch (P) less than its wire diameter (d) produced via a glancing angle deposition (GLAD) process.

### CROSS-REFERENCE TO RELATED APPLICATIONS

This application claims priority from and the benefit of U.S. Provisional Patent Application Ser. No. 62/272,213 filed on Dec. 29, 2015 and the benefit of U.S. Provisional Patent Application Ser. No. 62/408,836 filed on 17 Oct. 2016, the disclosures of which is hereby incorporated by reference.

### FIELD OF THE INVENTION

The present invention relates to a method to minimize helical pitch (P) of chiroplasmonic nanostructures to the molecular size-comparable scale. In particular, chiroplasmonic nanostructures, particularly those with a helical pitch (P) less than a wire diameter (d), can be used to induce plasmonic chirality via chirality transfer and used for chirality-related primary applications.

### BACKGROUND OF THE INVENTION

Chirality, a feature where an object cannot be superimposed onto its mirror image, substantially relates to the origin of life and biological functions. Nature generally adopts helices to express chirality, from the mega (e.g., galaxy) to macro (e.g., snail shells and honeysuckle winding around its support), micro (e.g., bacterial colonies) to super-molecular (e.g., DNA and peptide) scale. Chirality also exists in optical radiation, that is, helical propagation of circularly polarized light. Recently, it is of increasing interest to generate helical plasmonic metamaterials for studying the interaction with circularly polarized radiation, i.e., chiroplasmonics that may be used in smart optical coating, polarization sensitive imaging, and stereo display technologies. A series of methods have been developed to fabricate helical plasmonic metamaterials. First, chiral ligands are chemically grafted on achiral plasmonic nanoclusters to create helically atomic patterns on the plasmonic surfaces. Second, conventional lithographic techniques are utilized to stack multiple layers of a periodic plasmonic nanorod array in a helically twisted three-dimensional structure. Third, plasmonic nanoparticles are helically assembled without direct contact of each other, with use of helical templates including DNA, peptide, chiral mesoporous silica, inorganic nanohelices, organic spiral fibers, and chiral nematic films of cellulose nanocrystals. Fourth, without a chiral ligand or helical template. plasmonic helices are deposited by means of direct laser writing into a positive-tone photoresist followed by electrochemical deposition of gold, radio frequency plasma prior to electroless plating, multi-beam holographic lithography, colloidal nanohole lithography, focused ion beam induced deposition, electron beam induced deposition, and glancing angle deposition (GLAD).

Compared to the other fabrication techniques, GLAD enables a one-step, wafer-scale production of sculptured thin films on various kinds of substrates (e.g., opaque, transparent, conducting, insulating and flexible substrates); hence, the GLAD technique is gaining attention for generating chiroplasmonic devices for developing diverse chirality-related primary applications.

A helix is formed when a helical pitch (P) is larger than a wire diameter (d). Due to the limited development of nano-fabrication techniques, it is difficult to minimize d and consequently P to the deep subwavelength scale of <10 nm, prohibiting the investigation of chiroplasmonics towards the molecular size-comparable scale.

A helix is characterized by helical pitch (P), coil diameter (D), wire diameter (d), number of helical pitch (n) and height (H=nP), playing a role in engineering chiroptical activity that is mainly evaluated by circular dichroism (CD) and optical rotatory dispersion. Numerical simulation predicts a blue shift of the differential absorption maximum with a decrease of P, which is experimentally demonstrated by the fact that plasmonic microspirals with P>1 μm are chiroptically active in the spectrum of 3-6.5 μm, and plasmonic nanospirals with P<100 nm have chiroptical response in the UV-visible-near infrared spectrum. It is desirable to minimize P to be less than 10 nm which is comparable to molecular size. However, the P-minimization is geometrically limited by P>d. In terms of GLAD fabrication of plasmonic nanospirals, d will be significantly increased with substrate temperature (T_{sub}), owing to the temperature-assisted surface diffusion of adatoms. Fischer et. al. in “Mark, A. G.; Gibbs, J. G.; Lee, T. C.; Fischer, P., Hybrid nanocolloids with programmed three-dimensional shape and material composition. Nat. Mater. 2013, 12, 802-807” utilized liquid N₂ to control T_{sub} as low as −170° C., resulting in a generation of the state-of-the-art d of ˜30 nm and P of 34 nm. The P-minimization to the deep subwavelength scale substantially requires a further reduction in T_{sub}; however, it is very difficult to integrate such an extremely-low-T_{sub} cooling system in GLAD.

It is an objective of the present invention to provide the synthesis of molecular scale chiroplasmonic nanostructures with P<d, using GLAD.

### SUMMARY OF THE INVENTION

The present invention relates to a method to minimize the helical pitch (P) of chiroplasmonic nanostructures to the molecular size-comparable scale. In particular, chiroplasmonic nanostructures can be used to induce plasmonic chirality via chirality transfer and used for chirality-related primary applications.

In a first aspect of the present invention there is provided a chiroptically active plasmonic nanoparticle with a helical pitch (P) less than its wire diameter (d) produced via a glancing angle deposition (GLAD) process.

In a first embodiment of the first aspect of the present invention there is provided a chiroptically active plasmonic nanoparticle wherein said nanoparticle is chiroptically active in the UV-visible spectrum.

In a second embodiment of the first aspect of the present invention there is provided a chiroptically active plasmonic nanoparticle wherein said nanoparticle is chiroptically active in the spectrum range between 330 nm to 700 nm.

In a third embodiment of the first aspect of the present invention there is provided a chiroptically active plasmonic nanoparticle wherein said nanoparticle has hidden chirality.

In a fourth embodiment of the first aspect of the present invention there is provided a chiroptically active plasmonic nanoparticle wherein the hidden chirality is controlled by substrate rotation wherein a counter clockwise rotation produces said nanoparticle with a left-handed chirality and a clockwise rotation produces said nanoparticle with a right-handed chirality.

In a fifth embodiment of the first aspect of the present invention there is provided a chiroptically active plasmonic nanoparticle wherein said nanoparticle has a reversible water effect wherein when said nanoparticle is wet, its plasmonic mode is red shifted and amplified and said shifting and amplification of the plasmonic mode is reversed when said nanoparticle is dried.

In a sixth embodiment of the first aspect of the present invention there is provided a chiroptically active plasmonic nanoparticle wherein said nanoparticle is a silver nanoparticle or a gold nanoparticle or a copper nanoparticle or an aluminum nanoparticle.

In a seventh embodiment of the first aspect of the present invention there is provided a chiroptically active plasmonic nanoparticle wherein the nanoparticle is made of silver and the helical pitch (P) of said silver nanoparticle ranges between about 3.5 nm to about 70 nm and wherein the wire diameter (d) of said silver nanoparticle is no less than about 65 nm.

In a second aspect of the present invention there is provided a method to produce a chiroptically active plasmonic nanoparticle with a helical pitch (P) less than its wire diameter (d) comprising a glancing angle deposition process with substrate rotation during deposition, wherein a counter clockwise rotation produces said nanoparticle with a left-handed chirality and a clockwise rotation produces said nanoparticle with a right-handed chirality.

In a first embodiment of the second aspect of the present invention there is provided a method to produce a chiroptically active plasmonic nanoparticle wherein the substrate used is silver or gold or copper or aluminum.

In a second embodiment of the second aspect of the present invention there is provided a method to produce a chiroptically active plasmonic nanoparticle wherein the helical pitch (P) of a silver nanoparticle produced ranges between about 3.5 nm to about 70 nm and wherein the wire diameter (d) of said silver nanoparticle is no less than about 65 nm.

In a third embodiment of the second aspect of the present invention there is provided a method to produce a chiroptically active plasmonic nanoparticle wherein said nanoparticle is chiroptically active in the UV-visible spectrum.

In a fourth embodiment of the second aspect of the present invention there is provided a method to produce a chiroptically active plasmonic nanoparticle wherein said nanoparticle is chiroptically active in the spectrum range between 330 nm to 700 nm.

In a fifth embodiment of the second aspect of the present invention there is provided a method to produce a chiroptically active plasmonic nanoparticle wherein said nanoparticle has hidden chirality.

In a sixth embodiment of the second aspect of the present invention there is provided a method to produce a chiroptically active plasmonic nanoparticle wherein a substrate temperature (T_{sub}) used in said glancing angle deposition (GLAD) process is at approximately 0° C.

In a seventh embodiment of the second aspect of the present invention there is provided a method to produce a chiroptically active plasmonic nanoparticle wherein said nanoparticle has a reversible water effect wherein when said nanoparticle is wet, its plasmonic mode is redshifted and amplified and said shifting and amplification of the plasmonic mode is reversed when said nanoparticle is dried.

In a third aspect of the present invention there is provided a chiral sensor including the chiroptically active plasmonic nanoparticle.

In a first embodiment of the third aspect of the present invention there is provided a chiral sensor wherein the chiroptically active plasmonic nanoparticle positioned in a solvent.

In a second embodiment of the third aspect of the present invention there is provided a chiral sensor wherein the chiroptically active plasmonic nanoparticle positioned in an aqueous solution.

In a third embodiment of the third aspect of the present invention there is provided a chiral sensor wherein chiroptically active plasmonic nanoparticle is positioned in a biological fluid.

Those skilled in the art will appreciate that the invention described herein is susceptible to variations and modifications other than those specifically described.

The invention includes all such variation and modifications. The invention also includes all of the steps and features referred to or indicated in the specification, individually or collectively, and any and all combinations or any two or more of the steps or features.

Other aspects and advantages of the invention will be apparent to those skilled in the art from a review of the ensuing description.

### BRIEF DESCRIPTION OF THE DRAWINGS

The above and other objects and features of the present invention will become apparent from the following description of the invention, when taken in conjunction with the accompanying drawings, in which:

FIG. 1 shows the SEM tilted-viewing images of silver nanoparticles (AgNPs) with: average nominal helical pitch P of (a) 3.8 nm, (b) 3.5 nm, (c) 7.1 nm, (d) 7.0 nm, (e) 9.8 nm, (f) 10 nm, (g, h) 17 nm, (i) 32 nm, (j) 31 nm, (k) 49 nm, (l) 47 nm, (m) 66 nm, and (n) 63 nm; hidden helicity of the left-handed (LH: a, c, e, g, i, k, m) and right-handed (RH: b, d, f, h, j, l, n). (a-n) have a scale bar of 100 nm, as shown in (a). Insets on the top: Schematics diagrams of LH- and RH-AgNPs.

FIG. 2 shows the UV-visible spectral characterization of LH- (black lines) and RH-AgNPs (grey lines) with nominal P of ˜10 nm: (a) extinction; (b) CD; (c) anisotropy g factor. Insets: λₘₐₓ is the LSPR wavelength, and grey arrows mark the shoulder plasmonic peaks.

FIG. 3 shows the spectral characterization of LH- (in black) and RH-AgNPs (in dark gray) with nominal P that are presented in the plots: (a) CD; (b) anisotropy g factor.

FIG. 4 shows the plots of (a) |CDₘₐₓ|, (b) λ_{CD,max}, (d) |gₘₐₓ|, (e) λ_{g,max} versus nominal P of AgNPs, in terms of the chiroptical mode (UV: hole symbols; plasmonic: solid symbols) and hidden helicity (LH: in circle; RH: in triangle). The plots of (a) and (d) are linearly fitted to evaluate the chiroptical amplification slopes summarized in (c) and (f), respectively.

FIG. 5 shows a plot of the water contact angle (θ) versus P. The HF-treated RH-AgNPs with P less than 70 nm have θ<90°. Insets: photographs of water droplet applied to the surface of RH-AgNPs-17 (with nominal P of 17 nm, top left) and right-handed silver nanostructures (RH-AgNSs)-215 (with P of 215 nm, down right); cross-sectional SEM image of RH-AgNSs-215 deposited on Si wafer; schematic diagrams of RH-AgNP and RH-AgNS.

FIG. 6 shows the chiroptical water effect of (a) RH-AgNPs-17 and (b) RH-AgNSs-215, characterized by CD and extinction spectroscopies. The three spectra show pristine arrays in air, arrays immersed in water, and the water-treated arrays fully dried with N₂. The spectra are vertically shifted for clear comparison. Horizontal black dash lines: zero-CD axis for each CD spectrum. (b) Black and grey arrows mark the transverse (T) and longitudinal (L) plasmonic modes, respectively.

FIG. 7 shows the reversible water effect of the plasmonic mode of LH/RH-AgNPs-17: (a) λ_{Ext,max}; (b) λ_{CD,max}; (c) CDₘₐₓ; (d) Δλ_{Ext,max}; (e) Δλ_{CD,max}; (f) ΔCDₘₐₓ% versus m (the time of alternating wetting/drying processes). (a-c) LH-AgNPs-17: grey arrows represent the wetting processes, and black arrows the drying processes; diamonds represent data for the pristine array measured in air (m=0). (d-f): the wetting and drying processes are separated by a dash line at the value of zero; squares and circles represent LH- and RH-AgNPs-17, respectively; from the first eight (m of 1-8) alternating wetting/drying processes, the water effect indices are statistically evaluated to have an algebraic average value, standard deviation (following the symbol “±”), and the ratio of standard deviation to average value (denoted as the irreversibility, following standard deviation).

FIG. 8 shows the irreversible water effect on the transverse plasmonic mode of RH-AgNSs-215: (a) λ_{Ext,max}; (b) λ_{CD,max}; (c) CDₘₐₓ; (d) Δλ_{Ext,max}; (e) Δλ_{CD,max}; (f) ΔCDₘₐₓ% versus m. Refer to the description of FIG. 7.

FIG. 9 shows plot of aspect ratio (H/D) versus nominal P of LH-(dots) and RH-AgNPs (squares).

FIG. 10 shows Ag thin film with nominal thickness of 10 nm, deposited at an incident angle of 0° with respect to the direction normal to the substrate. The substrate was not rotated during the deposition. (a) Cross-sectional SEM image; (b) CD (black line) and extinction (grey line) spectra.

FIG. 11 shows the plots of a) λ_{Ext,max}; (b) λ_{CD,max}; (c) λ_{g,max}, (d) |gₘₐₓ| of the plasmonic mode versus nominal P of LH- (circles) and RH-AgNPs (squares). (d) The plots are linearly fitted to evaluate the slopes k_{lg(g)} as inset. (b) λ_{CD,max} of the shoulder plasmonic mode is highlighted with light grey background.

FIG. 12 shows the reversible water effect of the plasmonic mode of RH-AgNPs-17: (a) λ_{Ext,max}; (b) λ_{CD,max}; (C) CDₘₐₓ versus m.

FIG. 13 shows the reversible water effect on the plasmonic mode of LH-AgNPs-80: (a) λ_{Ext,max}; (b) λ_{CD,max}; (c) CDₘₐₓ; (d) Δλ_{Ext,max}; (e) Δλ_{CD,max}; (f) ΔCDₘₐₓ% versus m. Refer to the description of FIG. 7.

FIG. 14 shows the plot of Δλ_{Ext,max} of the LH-AgNPs-17 array versus refractive index n of the medium (from right top to left down): toluene, dichloromethane, hexane, acetone, ethanol, water, and air.

FIG. 15 shows a) Extinction and (b) CD spectra of LH- (black) and RH-AgNSs-P (grey). Black and grey arrows mark the transverse (T) and longitudinal (L) plasmonic modes, respectively. Nominal P of the samples are inset.

FIG. 16 shows the irreversible water effect of the L-plasmonic mode of RH-AgNSs-215: (a) λ_{CD,max}; (b) CDₘₐₓ; (c) Δλ_{CD,max}; (d) ΔCDₘₐₓ% versus m.

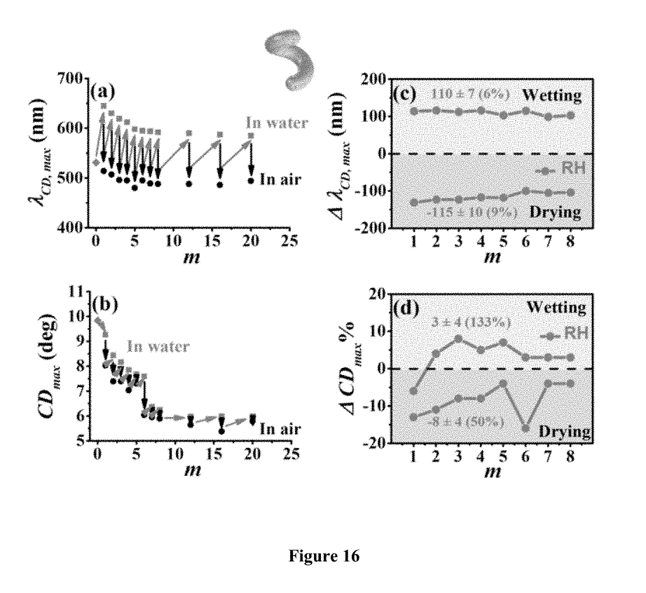

FIG. 17 shows the Plot of water contact angle (θ) versus m, in terms of RH-AgNSs-215 (dots) and RH-AgNPs-17 (squares). Insets: photographs of water droplets applied to the sample surfaces, marked with the measured θ.

FIG. 18 shows the optical spectra (a) CD, (b) Extinction, and (c) g-factor of chirality transfer from RH-AgNPs-P4.7 (black dotted line) to Au (black solid line) and LH-AgNPs-P4.4 (dark grey dotted line) to Au (dark grey solid line). Au is deposited on the AgNPs with a nominal thickness of 30 nm, using GLAD. Grey and dark grey backgrounds highlight the chiroptical activity of Ag and Au, respectively.

FIG. 19 shows the optical spectra (a) CD, (b) Extinction, and (c) g-factor of chirality transfer from RH-AgNPs-P4.7 (black dotted line) to Cu (black solid line) and LH-AgNPs-P4.4 (dark grey dotted line) to Cu (dark grey solid line). Cu is deposited on the AgNPs with a nominal thickness of 30 nm, using GLAD. Grey backgrounds highlight the chiroptical activity of Cu.

FIG. 20 shows the optical spectra (a, c) Extinction, and (b, d) CD of chirality transfer from RH-CuNPs-P3-H40 to Ag (a, b) and from RH/LH-CuNPs-P3-H40 to Al (c, d). Ag and Al are deposited on the CuNPs with a nominal thickness of 30 nm, using GLAD. Grey backgrounds highlight the chiroptical activity of Ag, Al and Cu, respectively.

### DETAILED DESCRIPTION

The present invention is not to be limited in scope by any of the specific embodiments described herein. The following embodiments are presented for exemplification only.

Chiroptically active plasmonic nanoparticles with a helical pitch (P) less than a wire diameter (d) are produced via a glancing angle deposition (GLAD) process. Various metals may be used to form chiroptically active plasmonic nanoparticles including silver, gold, copper, and aluminum.

The GLAD process may be carried out in a commercially available physical vapor deposition system capable of sustaining a high vacuum of 10⁻⁷-10⁻⁶ Torr. Bulk starting materials, typically in the form of pellets, are used as evaporation sources. The source materials may be evaporated at rates of <0.5 nm/s as monitored by a quartz crystal microbalance. The electron-beam accelerating voltage may range from 5 to 10 kV with an emission current of 10-100 mA. Glancing deposition angles of 70° to 87° with respect to the direction normal to the substrate may be used. A variety of substrates including insulators such as sapphire, semiconductors such as silicon, and metals such as silver, gold, copper, or aluminum may be used. During deposition, an ethanol/water cooling system may be used to control the substrate temperature. Substrate temperatures ranging from room temperature to roughly −70° C. may be used during deposition. To produce right-handed or left-handed nanoparticles, the substrate is rotated clockwise/counterclockwise at a rate Rᵣ (in units of degrees per second, or °/s) given by

$${R}_{r} = 360 \frac{{R}_{d}}{P}$$

where R_{d} is the deposition rate on the substrate surface and P is the helical pitch. The nominal P was calibrated by

$$P = \frac{H}{n}$$

where H is the helix height controlled to be roughly 100 nm, and n is the number of helical pitches equal to the number of circles in which the substrate was rotated. Details of a particular embodiment for silver nanoparticles is set forth in Example 1 below. The discussion of silver nanoparticles in the detailed description is based on the silver nanoparticles fabricated in Example 1.

Silver nanoparticles (AgNPs) with nominal P (in a range of 3-70 nm per revolution) smaller than d, were fabricated in Example 1, breaking the helix-geometrical limit. Apparently achiral nanoparticles have hidden helicity, resulting in chiroptical activity in the UV-visible spectrum. Hidden chiroptical activity in terms of circular dichroism (CD) and anisotropy g factor alters in sign with switching hidden helicity, and barely has a spectral shift but has a common logarithmical enhancement with nominal P. The nominal P can be minimized to as small as 4 nm with a reliably detectable chiroptical response.

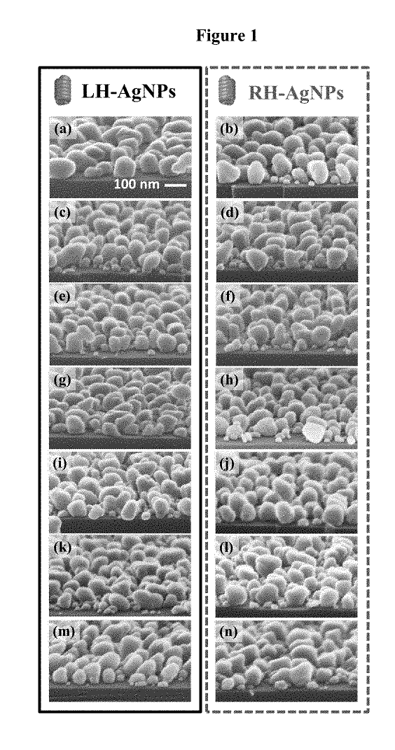

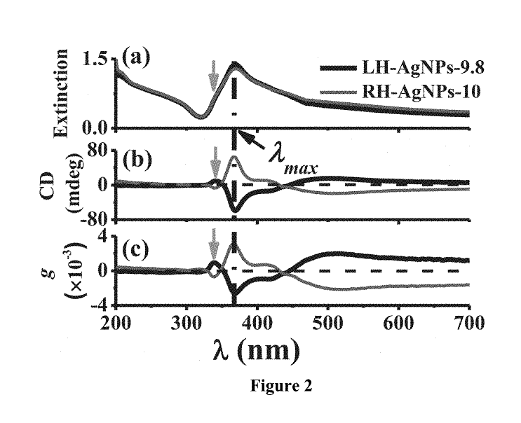

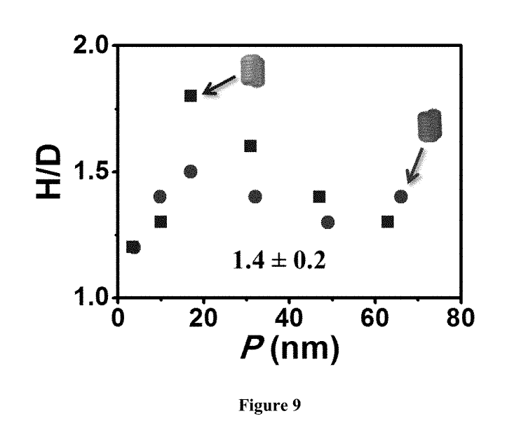

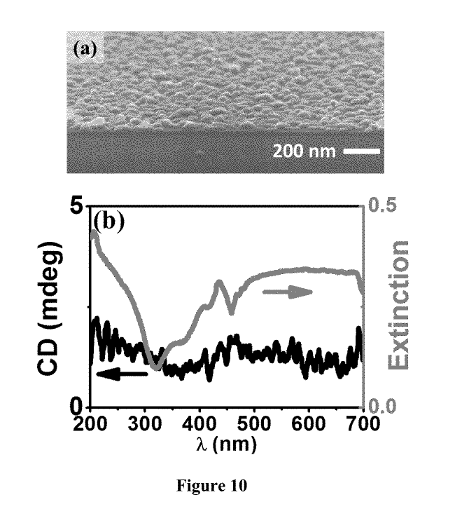

GLAD enables a deposition of a close-packed random array of AgNPs appearing to have non-helical profile, with a fixed H of ˜100 nm and nominal P engineerable in a range of 3-70 nm per revolution (i.e., nm/rev, FIG. 1). The hidden helicity is controlled by substrate rotation: counter-clockwise rotation produces the left-handed helicity (FIG. 1a, c, e, g, i, k, m), and clockwise rotation gives rise to the right-handed helicity (FIG. 1b, d, f, h, j, l, n). For easy communication, the inventors denote the left-handed AgNPs with nominal P as LH-AgNPs-P, whose mirror images are denoted as RH-AgNPs-P, where P represents the measured helical pitch (P=H/n, Table 1). For instance, LH-AgNPs-9.8 represents left-handed AgNPs with a nominal P of 9.8 nm (FIG. 2). The LH/RH-AgNPs-10 arrays have a broad UV-visible extinction reaching its maximum amplitude at the wavelength (λ) of ˜370 nm (FIG. 2a), ascribed to localized surface plasmon resonance (LSPR). The single-peak extinction feature is ascribed to the fact that the aspect ratio of H/D, evaluated as 1.3 for LH-AgNPs-9.8 and 1.4 for RH-AgNPs-10 (FIG. 9), is close to 1. Correspondingly, the arrays have chiroptical response at wavelengths of 330-700 nm, characterized by CD (FIG. 2b). The CD spectra are composed of the plasmonic peak at 370 nm, a peak at ˜340 nm, and bisignated peaks in the visible region. The 340-nm CD peak is assigned to the shoulder plasmonic mode, as there is a shoulder extinction peak at 340 nm. Numerical simulation revealed that the visible chiroptical activity stems from the optical interaction (including reflection, scattering and/or trapping) of the AgNP array. The shoulder plasmonic and visible modes are chiroptically weaker than the plasmonic mode. The anisotropy g factor can be calculated by

$$g = \frac{CD}{16500 A}$$

where CD is the ellipticity (units: millidegree, or mdeg) and A is the extinction. The arrays have the plasmonic g factor of ˜4×10⁻³ (FIG. 2c). The CD spectrum flips around the zero-CD axis as the hidden chirality is switched, illustrating that the hidden helicity leads to intrinsic chiroptical activity of AgNPs with P<d. The chiroptical origin can be further demonstrated by the fact that without substrate rotation, the deposited AgNPs lack hidden chirality and chiroptical response (FIG. 10).

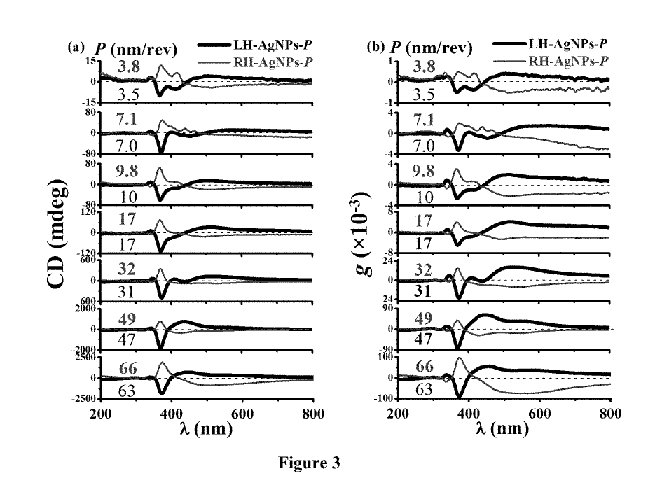

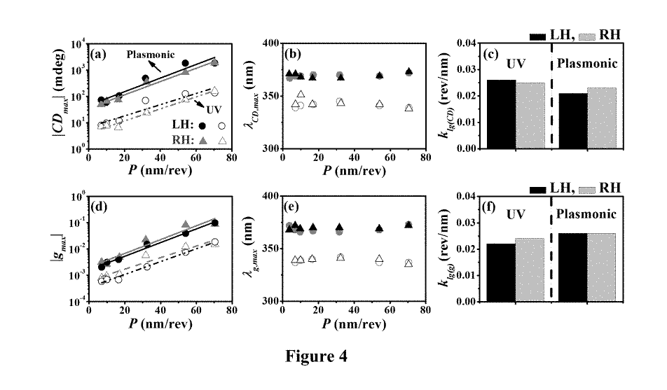

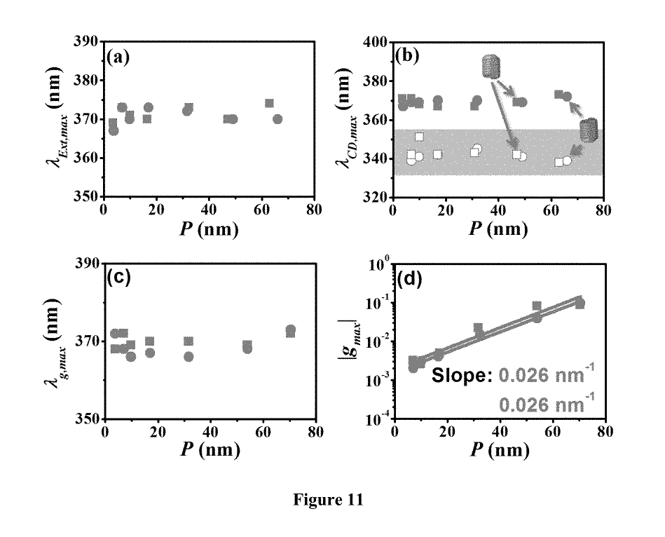

The chiral AgNP arrays, with a nominal P in the range of 3-70 nm and H of ˜100 nm, were spectroscopically characterized in the UV-visible region. The AgNP arrays have a P-independent extinction (FIG. 3a) but P-sensitive chiroptical response (FIG. 3b). The UV-visible extinction tends to correlate with H, accounting for the independence on P. The hidden chiroptical activity will be briefly discussed. First, LSPR barely shifts with nominal P (FIGS. 3a and 11a); neither do the (shoulder) plasmonic CD (FIGS. 11b and 11b) and g factor (FIG. 11c) modes. As well known, the LSPR substantially correlates to NP structures. Varying with nominal P, AgNPs tend to have a relatively small distribution of the aspect ratio of H/D that is evaluated as 1.4±0.2 (FIG. 9), accounting for the small LSPR spectral shift with increasing nominal P. Second, the plasmonic CD (and g factor) mode tends to have a common logarithmic increase with nominal P (FIGS. 4a and 11d). The chiroptical amplification slope can be evaluated by

$${k}_{lg ( CD )} = \frac{d ( lg \vert {CD}_{max} \vert )}{dP}$$

$${k}_{lg ( g )} = \frac{d ( lg \vert {g}_{max} \vert )}{dP}$$

where CDₘₐₓ and gₘₐₓ represent the amplitude of CD and g factor at the wavelength of λ_{CD,max} and λ_{g,max}, respectively. The slope of the plasmonic mode varies in a small range of 0.021-0.026 nm⁻¹ with the hidden AgNP chirality, and is nearly equal to that of the shoulder plasmonic mode (FIG. 4b). Given the LSPR wavelength of ˜370 nm, an increase of the nominal P from 3.5 to 66 nm gives rise to a significant enhancement of the P-LSPR wavelength coupling. As a result, large P, accompanied with the electromagnetic coupling of neighboring AgNPs in the close-packed arrays, facilitates asymmetric LSPR excitation under circularly polarized incident, accounting for the P-induced amplification of the chiroptical activity. Third, the visible mode also increases the CD amplitude with increasing nominal P (FIG. 3b). The visible chiroptical mode originates from the optical interaction of the AgNP arrays, so as to vary sensitively with the spacing and NP structure of the AgNP array. On a flat surface, GLAD typically generates a random array with little reproducible control of the spacing. GLAD was operated at T_{sub} of 0° C., at which Ag adatom diffusion on the deposited AgNPs could not be effectively prohibited; hence, AgNPs appear to have irregular structures. As a result, the array has the broad extinction feature in the visible regime, and the visible chiroptical mode sometimes has irregular CD signals, making it difficult to quantitatively investigate the chiroptical dependence on nominal P.

Chiral plasmons may be used for chirality-related determinations in analytical chemistry, pharmacology, and biology. Left-handed and right-handed versions of the same molecule, known as enantiomers, may significantly differ in their chemical and biological actions. In some cases, one enantiomer may have a therapeutic pharmacological activity while the other enantiomer may be hazardous. Consequently, it is important to be able to distinguish between enantiomers. Chiroptical methods typically measure small differences, or dissymmetries, in the interaction of left and right circularly polarized light, the chiral probe, with a chiral material to determine the enantiomer present. Chiral plasmons tend to amplify the chiroptical activity of enantiomers, leading to an enhancement of enantiomer differentiation.

In a recent referenced entitled Expanding the Chiral Toolbox: Recent chiral advances demonstrate promise for API synthesis by Cynthia A. Challener, Pharmaceutical technology, Volume 40, Issue 7, pages 28-29, Jul. 2, 2016 (retrieved from http://www.pharmtatech.com/expanding-chiral-toolbox) it is stated that:

“The majority of small-molecule drugs in development today contain chiral centers, and according to Global Industry Analysts (GIA) nearly 95% of drugs will be chiral by 2020. GIA estimates that the global chiral technology market, which is dominated by pharmaceutical applications (followed by agrochemicals and flavors and fragrances), will reach $5.1 billion by 2017.

Because FDA requires manufacturers to investigate the properties (physicochemical, pharmacokinetic, etc.) of all enantiomers/diastereomers of chiral drugs to determine their individual safety and efficacy, the development of efficient chiral synthesis technologies remains a primary target for many academic and industrial researchers.”

Thus, it is pertinent herein that one embodiment of the present invention has applications in chiral sensing for drugs development.

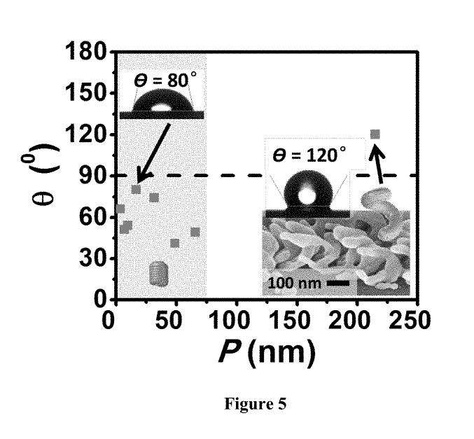

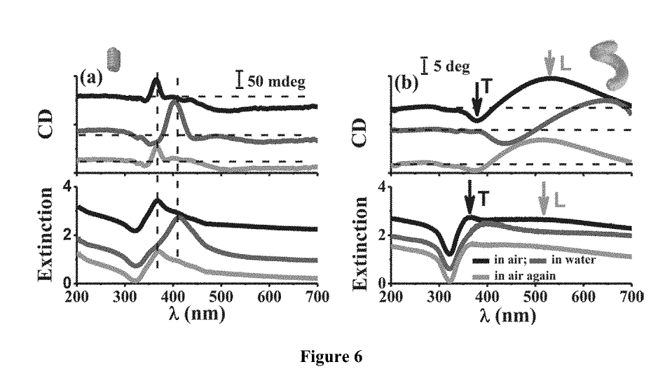

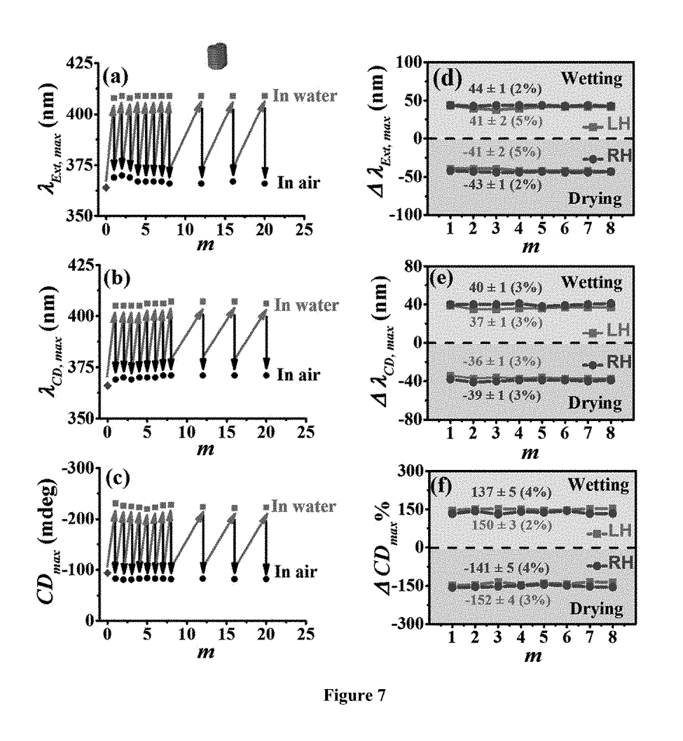

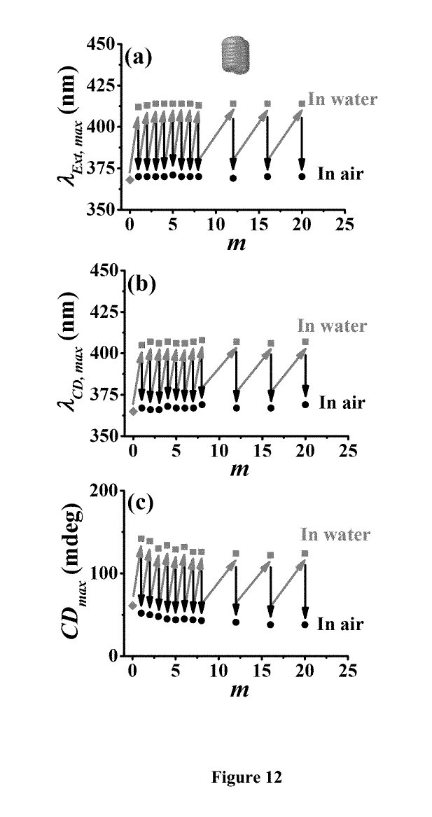

Because chiral sensing typically takes place in solutions, the effect of water on the optical activity of fabricated chiral plasmons was analyzed. After removal of surface oxides/contaminants using 5% HF, the RH-AgNPs-P arrays (P: 3-70 nm) are hydrophilic, with water contact angles (θ)<90°; but the RH-AgNSs-215 array is hydrophobic, with a θ of 120° (FIG. 5). This result illustrates that the HF treatment causes AgNPs to have higher surface energy than AgNSs. Immersing the hydrophilic RH-AgNPs-17 array in water not only causes the LSPR extinction and CD peaks to concurrently redshift by roughly 40 nm but also amplifies them, that is, the chiroptical water effect (FIG. 6a). The subsequent drying process makes the extinction and CD return to the original level, showing a reversible water effect that can be further confirmed by the multiple alternating wetting/drying processes (FIGS. 7 and 12). The wetting process can be quantitatively evaluated by

$$Δ {λ}_{Ext , max} = ( {λ}_{max , water , m} - {λ}_{max , air , m - 1} ) {\vert}_{Ext} \\ Δ {λ}_{CD , max} = ( {λ}_{max , water , m} - {λ}_{max , air , m - 1} ) {\vert}_{CD} \\ Δ {CD}_{max } \% = \frac{( {CD}_{max , water , m} - {CD}_{max , air , m - 1} )}{{CD}_{max , air , m = 0}} \times 100 \%$$

where the subscript “Ext” represents extinction, “water” the medium of water, “air” the medium of air, and “m” the number of alternating wetting/drying processes. The drying processes can be quantitatively characterized by

$$Δ {λ}_{Ext , max} = ( {λ}_{max , water , m} - {λ}_{max , air , m} ) {\vert}_{Ext} \\ Δ {λ}_{CD , max} = ( {λ}_{max , water , m} - {λ}_{max , air , m} ) {\vert}_{CD} \\ Δ {CD}_{max} \% = \frac{( {CD}_{max , water , m} - {CD}_{max , air , m} )}{{CD}_{max , air , m = 0}} \times 100 \%$$

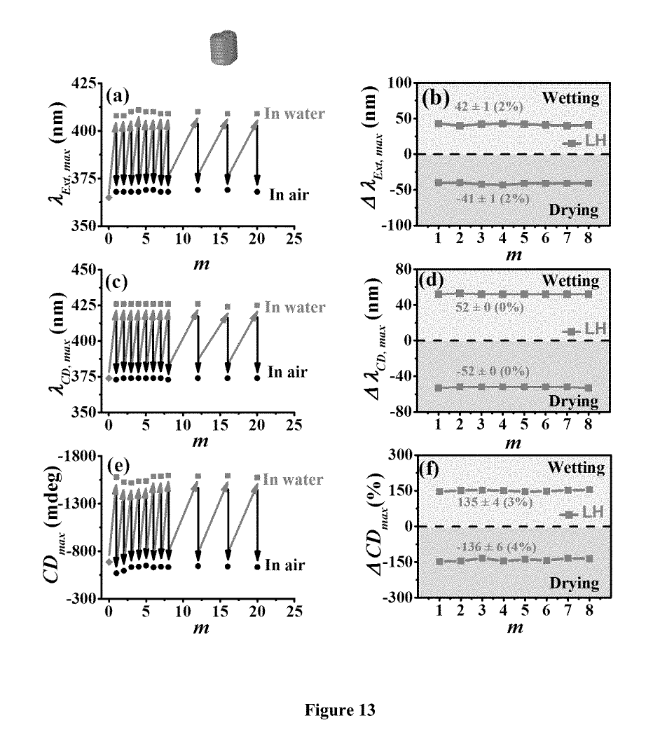

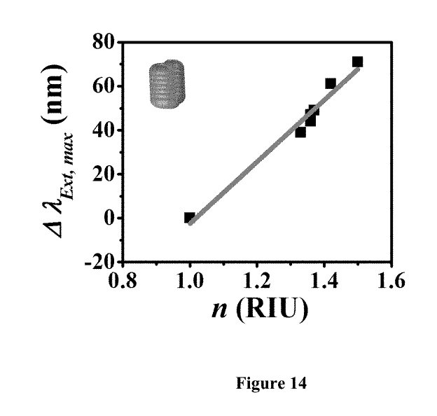

The multiple alternating wetting/drying processes consistently cause the LSPR extinction and CD peaks to have concurrent red/blue shifts (Δλ_{Ext,max}≈Δλ_{CD,max}, FIG. 7a versus b), and lead to an amplification/reduction of the plasmonic CD (FIG. 7c). For the LH-AgNPs-17 array, the first eight (m: 0-8) alternating wetting and drying processes lead to Δλ_{Ext,max} of 41±2 nm and (−41)±2 nm (FIG. 7d), Δλ_{CD,max} of 37±1 nm and (−36)±1 nm (FIG. 7e), and ΔCDₘₐₓ% of 150±3% and (−152)±4% (FIG. 7f), respectively. All the indices of the water effect have ratios of standard deviation to algebraic average value (denoted as the irreversibility) of not more than 5%, and the wetting indices are symmetric around the zero-value axis with the drying ones. This leads to the conclusion that the LH-AgNPs-17 array has an excellent reversible water effect on chiroptical activity, which can also be seen with the RH-AgNPs-17 array (FIGS. 7d-f and 12). The hidden chirality of AgNPs has little effect on the wetting/drying indices. It is a general phenomenon that the AgNPs with P<d have the reversible water effect on the chiroptical activity, for example, P of −80 nm (FIG. 13). Not only water but also other organic molecules will have the reversible effect on LSPR of achiral plasmonic nanostructures. Furthermore, LSPR of LH-AgNPs-17 redshifts linearly with increasing refractive index of the surrounding medium (FIG. 14), consistent with the theoretical prediction.

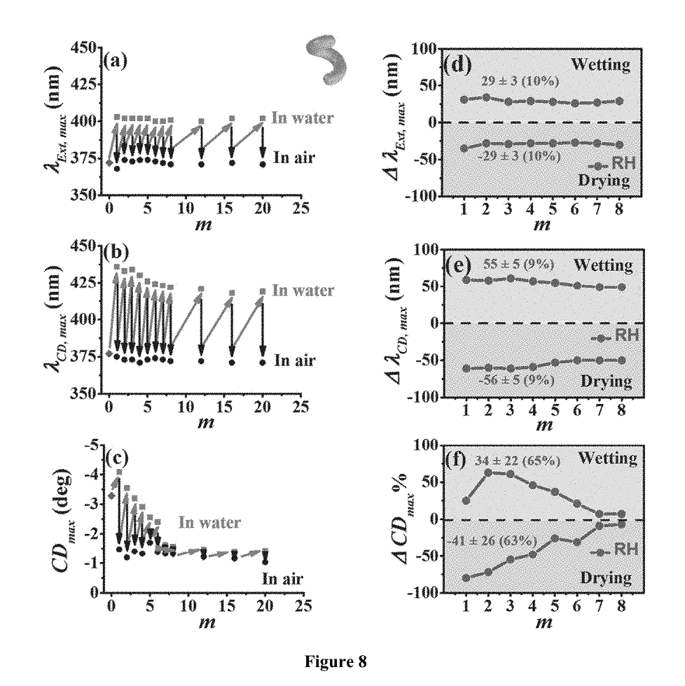

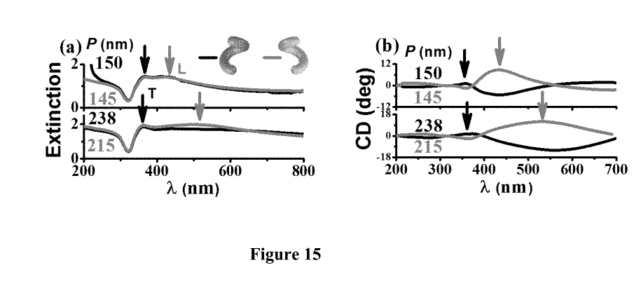

The water effect of AgNPs was compared with that of AgNSs. The RH-AgNSs-215 array with a P of 215 nm has transverse (T) LSPR at a wavelength of roughly 370 nm and longitudinal (L) LSPR at roughly 520 nm (FIGS. 6b and 15). Correspondingly, the AgNS array has a T-plasmonic CD peak at 375 nm with a negative sign and a broad L-plasmonic CD peak centered at ˜540 nm with a positive sign. Analogous to the chiroptical water effect of AgNPs, the wetting/drying process leads to the red/blue shift of the extinction and CD spectra and CD amplification/weakening of the T- and L-plasmonic modes. In terms of Δλ_{Ext,max} and Δλ_{CD,max} of the T- and L-plasmonic modes, the first eight alternating wetting/drying processes provide the irreversibility of less than 10% and causes Δλ_{Ext,max} and Δλ_{CD,max} to switch symmetrically around the zero-axis (FIGS. 8a, b, d, e and 16a, c). This illustrates that the chiroptical activity of AgNSs has a reversible water effect with respect to the resonance wavelength, although the reversibility is less than that of AgNPs. However, the water effect of AgNSs markedly differs from that of AgNPs. First, AgNPs have Δλ_{Ext,max}≈Δλ_{CD,max} (FIG. 7d versus 7e), indicating that the water effect causes an in-phase extinction-CD shift. However, AgNSs have) Δλ_{Ext,max}<Δλ_{CD,max} (FIG. 8d versus 8e), that is, an out-of-phase shift where the CD shifts more than the extinction. Second, for LSPR at ˜370 nm, Δλ_{Ext,max} of AgNPs is larger than that of AgNSs (FIG. 7d versus 8d), but Δλ_{CD,max} of AgNPs is smaller than that of AgNSs (FIG. 7e versus 8e). Third, ΔCD % of AgNSs has irreversibility in the range of 50-133% and does not change symmetrically with alternating wetting/drying processes (FIGS. 8c, f and 16b, d). This illustrates that AgNSs have an irreversible water effect on the CD amplitude. The T- and L-plasmonic CD of AgNSs tends to quench with increasing m, becoming saturated at m>7 (FIGS. 8c, f and 16b, d).

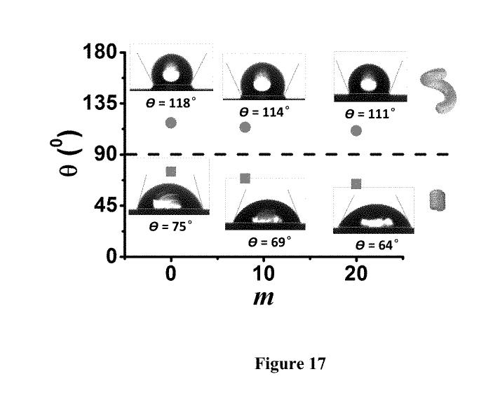

Although θ slightly decreases with increasing m, RH-AgNSs-215 and RH-AgNPs-17 remain hydrophobic and hydrophilic, respectively (FIG. 17). The AgNSs appear to have helical structures, and the AgNPs have non-porous structures. As a result, the AgNS arrays tend to be more porous than the AgNP arrays. The hydrophilic AgNP arrays with low array porosity can be facilely wet and dried, accounting for the reversible water effect on the chiroptical activity. On the contrary, the hydrophobic AgNS arrays with high array porosity lead to the irreversible water effect.

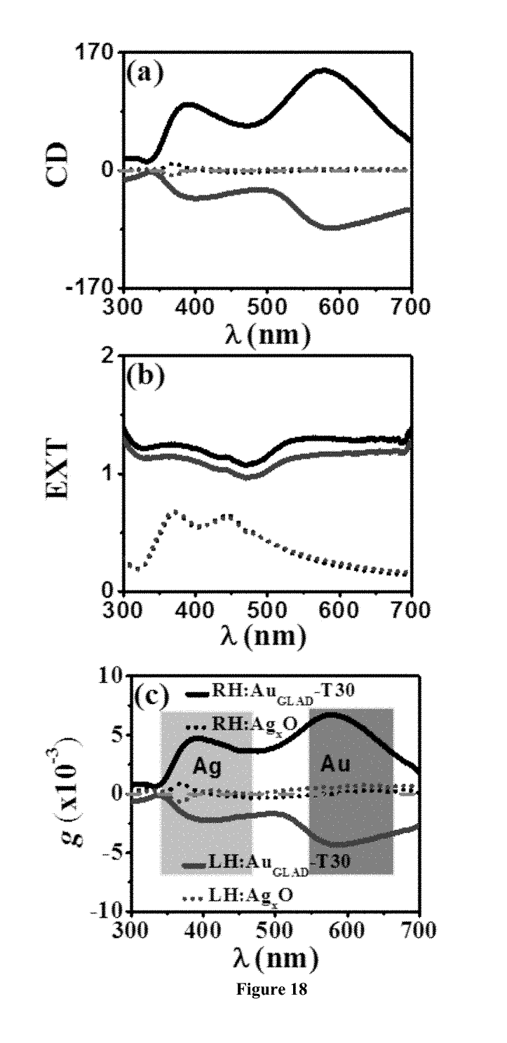

Chiral nanoplasmons can be used to induce plasmonic chirality via chirality transfer. For example, when Au was deposited onto chiral AgNPs with a nominal thickness of 30 nm, the achiral Au nanocoatings cause an amplification of extinction in the visible region of 500-700 nm (FIG. 18b), and a new broadband CD peak centered at ˜600 nm (FIG. 18a) that is ascribed to LSPR of the achiral Au nanocoatings. The induced CD and anisotropic g-factor spectra of the Au nanocoatings flips around the zero-axis while the hidden handedness of the underlying chiral AgNPs is switched (FIG. 18c). It is strongly illustrated that this is the plasmonic chirality of the Au nanocoatings is induced by the underlying chiral nanoplasmons.

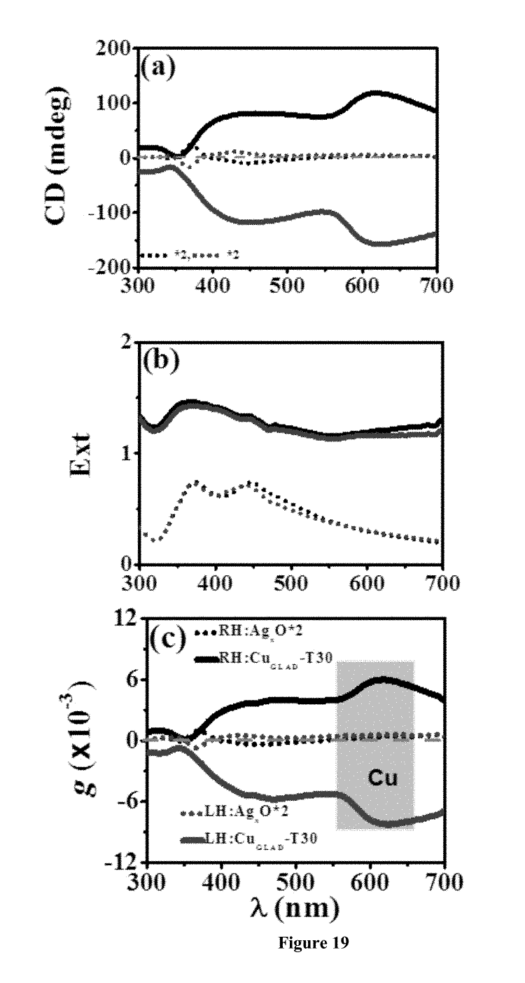

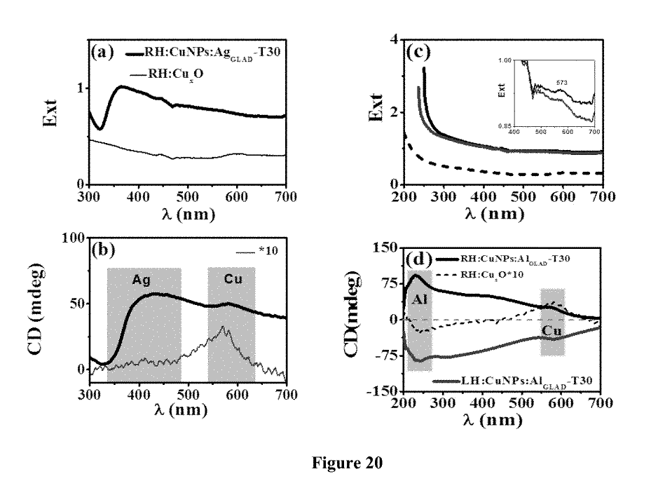

Furthermore, the chirality transfer from the underlying chiral NPs to the plasmonic nanocoatings occurs on diverse nanocoating materials, such as Cu (FIG. 19), Ag and Al (FIG. 20).

### Example 1

GLAD: In a physical vapor deposition system (JunSun Tech Co. Ltd., Taiwan) with a high vacuum of 10⁻⁷-10⁻⁶ Torr, Ag pellets (99.99%, Kurt J. Lesker) were evaporated at a rate of 0.3 nm/s as monitored by a quartz crystal microbalance, using an electron-beam accelerating voltage of 8.0 kV and emission current of 15-25 mA. At a deposition angle of 86° with respect to the direction normal to the substrate, Ag was deposited on sapphire (MTL Hong Kong) and Si wafer (Semiconductor Wafer, Inc.) over an area of 1.5×1.5 cm². During deposition, an ethanol/water cooling system was used to control T_{sub} at roughly 0° C. To produce RH/LH-AgNPs-P, the substrate was rotated clockwise/counterclockwise at a rate Rᵣ (in units of degrees per second, or °/s) given by

$${R}_{r} = 360 \frac{{R}_{d}}{P}$$

where R_{d} is the deposition rate on the substrate surface calibrated as 0.045 nm/s, and P is the helical pitch. To make P decrease from 70.4 to 3.2 nm, Rᵣ was controlled to increase from 0.23 to 5.0°/s. The nominal P was calibrated by

$$P = \frac{H}{n}$$

where H is the helix height controlled to be roughly 100 nm, and n is the number of helical pitch equal to how many circles the substrate was rotated in. The engineering of structural parameters of RH/LH-AgNPs-P is summarized in Table 1. When Rᵣ was reduced to 0.11 and 0.07°/s, Ag was sculptured to form AgNSs with P of 150 and 231 nm, respectively. At the deposition angle of 0° and T_{sub} of ˜0° C., a substrate that was not rotated was deposited with 10-nm-thick Ag, leading to the generation of AgNPs without hidden chirality.

Measurement of CD and UV-Visible Extinction Spectra:

BioLogic CD (MOS 500) and DSM 1000 CD (Olis Inc.) were used to monitor the CD spectra of AgNPs and AgNSs deposited on sapphire under circularly polarized incident light along the substrate normal, respectively. The sample was rotated clockwise at 0.2 rpm to monitor CD in the wavelength range of 200-800 nm, to eliminate linear birefringence. Eight CD spectra were subsequently recorded and algebraically averaged to obtain a CD spectrum of the sample. UV-visible extinction spectra of all the samples were measured using BioLogic CD (MOS 500).

A liquid cell (with a path length of 1 mm and volume of approximately 0.08 ml) was used to evaluate the effect of aqueous solvent on the chiroptical activity of a sample. First, a sample deposited on sapphire was etched in 5% HF for 15 s to remove surface oxides/contaminants, and then sufficiently rinsed with DI water (18.2 MΩ, Milli-Q reference water purification system fed with campus distilled water) and dried with N₂. Second, the HF-treated sample was immediately transferred into the liquid cell to measure the CD and extinction spectra. Third, 0.08 ml of DI water was injected into the cell to completely immerse the sample in DI water (i.e., the wetting process), and then the CD and extinction spectra were recorded. Fourth, DI water was completely removed from the cell by sufficiently drying with N₂ (i.e., the drying process) to record CD and extinction spectra. Fifth, multiple alternating wetting and drying processes were applied to study the reversibility of the aqueous solvent effect at the same spot on a sample.

Without substrate rotation, GLAD of Au (99.999%, Kurt J. Lesker), Cu (99.9999%, ZNXC, China) and Al (99.999%, ZNXC, China) was operated at a of 0° and T_{sub} of −40° C., using an electron-beam accelerating voltage of 8.0 kV. R_{d} of Au was controlled as 0.1 nm/s using emission current of 52-65 mA (Cu, 0.1 nm/s, 20-30 mA; Al, 0.1 nm/s, 35-45 mA). The nominal thickness of Au, Cu and Al were controlled to be 30 nm, monitored by the QCM.

Structure Characterization:

The as-deposited substrates were mechanically split, leaving the freshly exposed surfaces for SEM characterization (Oxford, LEO 1530).

Measurement of Water Contact Angle:

A 2-μl droplet of DI water was applied to a sample to measure the contact angle using a contact angle meter (CA100A, Innuo Shanghai).

TABLE 1
Engineering of helical pitch P · P_{d} represents the designed P · R_{d}
(the deposition rate of Ag) was controlled at 0.045 nm/s, calibrated
at the deposition angle of 86° with respect to the direction normal
to the substrate. For each sample, multiple (not less than 10)
measurements were performed to evaluate H with algebraic average
value and standard deviation.

| | P_{d} = 360 | | | | | P = H/n | |
|---|---|---|---|---|---|---|---|
| Rᵣ | R_{d}/Rᵣ | H (nm) | | n | | (nm) | |
| (°/s ) | (nm) | LH | RH | LH | RH | LH | RH |
| 0.07 | 231.4 | 238 ± 11 | 215 ± 4 | 1 | 1 | 238 ± 11 | 215 ± 4 |
| 0.11 | 150.0 | 150 ± 8 | 145 ± 5 | 1 | 1 | 150 ± 8 | 145 ± 5 |
| 0.23 | 70.4 | 95 ± 4 | 90 ± 6 | 1.4 | 1.4 | 66 ± 3 | 63 ± 4 |
| 0.3 | 54.0 | 91 ± 4 | 87 ± 5 | 1.9 | 1.9 | 49 ± 2 | 47 ± 3 |
| 0.5 | 32.4 | 92 ± 4 | 95 ± 4 | 2.9 | 3.1 | 32 ± 1 | 31 ± 1 |
| 1.0 | 16.2 | 97 ± 8 | 94 ± 5 | 5.6 | 5.7 | 17 ± 1 | 17 ± 1 |
| 1.5 | 10.8 | 90 ± 7 | 94 ± 4 | 9.2 | 9.4 | 9.8 ± 0.8 | 10.0 ± 0.4 |
| 2.3 | 7.0 | 99 ± 5 | 98 ± 5 | 14.0 | 14.0 | 7.1 ± 0.4 | 7.0 ± 0.4 |
| 5.0 | 3.2 | 113 ± 7 | 104 ± 6 | 30.0 | 30.0 | 3.8 ± 0.2 | 3.5 ± 0.2 |

The LSPR spectral shift (Δλ_{Ext,max}) can be described as:

$$Δ {λ}_{Ext , max} = {m}^{′} ( 1 - {e}^{- \frac{2 T}{{l}_{d}}} ) ( n - {n}_{air} ) = - {m}^{′} ( 1 - {e}^{- \frac{2 T}{{l}_{d}}} ) + {m}^{′} ( 1 - {e}^{- \frac{2 T}{{l}_{d}}} ) n$$

where m′ is the sensitivity factor (in nm per refractive index unit, or nm/RIU), n is the refractive index of the medium, nₐᵢᵣ is the refraction index of air (equal to 1 RIU), T is the effective thickness of silver oxides on AgNPs, and I_{d} is the electromagnetic field decay length. The above equation shows that the interception has an absolute value equal to the slope, but the sign opposite to the slope. Evaluated from the linear fitting of FIG. 14, the intercept is (−142.7)±13.8 nm and the slope is 140.2±10.3 nm/RIU, in good agreement with the above equation.

The LSPR of AgNSs is composed of the transverse (T) mode at a wavelength of ˜365 nm and longitudinal (L) mode in the visible region (FIG. 15a). The L mode redshifts with increasing aspect ratio l/d, where d is the wire diameter and l is the helical length, given by

l=d+\sqrt{[nπ(D−d)]²+(nP−d)²}

However, the T mode shifts only slightly with the aspect ratio. RH-AgNSs-145 with a P of 145 nm have an aspect ratio of 4.6, and RH-AgNSs-215 with a P of 215 nm have an aspect ratio of 5.6. Both in the extinction and CD spectra, the increase in the aspect ratio from 4.6 to 5.6 causes the L mode to redshift from the wavelength of 422 to 518 nm but has little effect on the T mode (FIG. 15a,b). At T_{sub} of −170° C., Fischer et al. fabricated the array of copper NSs with P varying from 20 to 100 nm and reported that the plasmonic CD in the visible region redshifts with increasing P, consistent with the inventors' results of the redshift of the L mode.

### INDUSTRIAL APPLICATION

Molecular scale chiroplasmonic nanostructures of the present invention find application in chiral sensing for determining enantiomers in chemical, biological, and pharmacological applications. Currently, more than 80% of pharmaceuticals on the market are chiral compounds. Usually, one enantiomeric configuration has a positive effect, but another may have a negative or even fatal side effect. Since 1992, the U.S. Food and Drug Administration has mandatorily required a full pharmacokinetic and toxicological evaluation of each stereoisomer of chiral drugs. It is therefore necessary to separate one enantiomer from another, and to differentiate one absolute configuration from another (i.e., enantiodifferentiation). The utilization of the invented plasmonic nanoparticles can essentially enhance the enantiodifferentiation, by amplifying the optical activity of pharmaceutical enantiomers.

In one aspect, the chiroplasmonic nanostructures have a helical pitch (P) less than the wire diameter of the helix to produce effects on the order of a molecular level to enable determination of smaller molecules.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

1. A chiroptically active plasmonic nanoparticle with a helical pitch (P) less than its wire diameter (d) produced via a glancing angle deposition (GLAD) process.

2. The chiroptically active plasmonic nanoparticle according to claim 1 wherein said nanoparticle is chiroptically active in the UV-visible spectrum.

3. The chiroptically active plasmonic nanoparticle according to claim 1 wherein said nanoparticle is chiroptically active in the spectrum range between 330 nm to 700 nm.

4. The chiroptically active plasmonic nanoparticle according to claim 1 wherein said nanoparticle has hidden chirality.

5. The chiroptically active plasmonic nanoparticle according to claim 4 wherein the hidden chirality is controlled by substrate rotation wherein a counter clockwise rotation produces said nanoparticle with a left-handed chirality and a clockwise rotation produces said nanoparticle with a right-handed chirality.

6. The chiroptically active plasmonic nanoparticle according to claim 1 wherein said nanoparticle has a reversible water effect wherein when said nanoparticle is wet, its plasmonic mode is red shifted and amplified and said shifting and amplification of the plasmonic mode is reversed when said nanoparticle is dried.

7. The chiroptically active plasmonic nanoparticle according to claim 1 wherein said nanoparticle is a silver nanoparticle or a gold nanoparticle or a copper nanoparticle or an aluminum nanoparticle.

8. The chiroptically active plasmonic nanoparticle according to claim 7 wherein the nanoparticle is silver and the helical pitch (P) of said silver nanoparticle ranges between about 3.5 nm to about 70 nm and wherein the wire diameter (d) of said silver nanoparticle is no less than about 65 nm.

9. A method to produce a chiroptically active plasmonic nanoparticle with a helical pitch (P) less than its wire diameter (d) comprising a glancing angle deposition process with substrate rotation during deposition, wherein a counter clockwise rotation produces said nanoparticle with a left-handed chirality and a clockwise rotation produces said nanoparticle with a right-handed chirality.

10. The method according to claim 9 wherein the substrate used is silver or gold or copper or aluminum.

11. The method according to claim 10 wherein the helical pitch (P) of a silver nanoparticle produced ranges between about 3.5 nm to about 70 nm and wherein the wire diameter (d) of said silver nanoparticle is no less than about 65 nm.

12. The method according to claim 9 wherein said nanoparticle is chiroptically active in the UV-visible spectrum.

13. The method according to claim 9 wherein said nanoparticle is chiroptically active in the spectrum range between 330 nm to 700 nm.

14. The method according to claim 9 wherein said nanoparticle has hidden chirality.

15. The method according to claim 9 wherein a substrate temperature (T_{sub}) used in said glancing angle deposition (GLAD) process is approximately 0° C. to approximately −70° C.

16. The method according to claim 9 wherein said nanoparticle has a reversible water effect wherein when said nanoparticle is wet, its plasmonic mode is redshifted and amplified and said shifting and amplification of the plasmonic mode is reversed when said nanoparticle is dried.

17. A chiral sensor including the chiroptically active plasmonic nanoparticle according to claim 1.

18. The chiral sensor of claim 17 wherein the chiroptically active plasmonic nanoparticle is positioned in a solvent.

19. The chiral sensor of claim 17 wherein the chiroptically active plasmonic nanoparticle is positioned in an aqueous solution.

20. The chiral sensor of claim 17 wherein chiroptically active plasmonic nanoparticle is positioned in a biological fluid.
